(19) United States
(12) Patent Application Publication
(10) Pub. No.: US 2023/0324793 A1
(43) Pub. Date: Oct. 12, 2023

(54) PHOTOSENSITIVE RESIN COMPOSITION AND CURED PRODUCT

(71) Applicant: eChem Solutions Corp., Taoyuan (TW)

(72) Inventors: Hsiao-Chi Chiu, Taoyuan (TW); Jui-Yu Hsu, Taoyuan (TW)

(73) Assignee: eChem Solutions Corp., Taoyuan (TW)

(21) Appl. No.: 18/297,004

(22) Filed: Apr. 7, 2023

(30) Foreign Application Priority Data
Apr. 8, 2022 (TW) 111113394

(51) Int. Cl. G03F 7/029

(52) U.S. Cl. CPC G03F 7/029; G03F 7/0048

(57) ABSTRACT

A photosensitive resin composition and a cured product are provided. The photosensitive resin composition includes an alkali-soluble resin (A), polymerizable monomer (B), a thermal acid generator (D), a photoinitiator (E) and a solvent (F). The weight average molecular weight of the alkali-soluble resin (A) is 5,000-40,000. The polymerizable monomer (B) includes an epoxy monomer (B1), ethylenically unsaturated monomer (B2) or the combination thereof. The thermal acid generator (D) includes hexafluoroonium salt. The epoxy monomer (B1) includes a compound represented by following Formula (B-1).

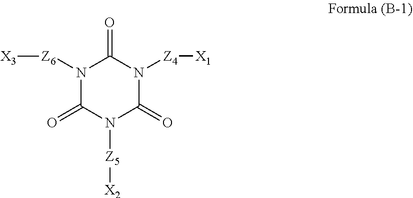

In Formula (B-1), the definition of X₁ to X₃ and Z₄ to Z₆ are the same as defined in the detailed description.

### CROSS-REFERENCE TO RELATED APPLICATION

This application claims the priority benefit of Taiwan application serial no. 111113394, filed on Apr. 8, 2022. The entirety of the above-mentioned patent application is hereby incorporated by reference herein and made a part of this specification.

### BACKGROUND

### Technical Field

The invention relates to a resin composition, and more particularly, to a photosensitive resin composition and a cured product.

### Description of Related Art

With the vigorous development of optical elements, in order to expand their application level, the demand for the size miniaturization and multifunctional performance of optical elements gradually increases. However, the cured product formed by the photosensitive resin composition currently used for manufacturing optical elements has the phenomena of poor transmittance and poor curvature change rate of developed residual film corresponding to exposure amount, such that the performance of the optical element made thereof is further influenced.

### SUMMARY

Accordingly, the invention provides a photosensitive resin composition and a cured product that may have the following characteristics: good light transmittance, curvature change rate of developed residual film corresponding to exposure amount, developability, high-temperature resistance and low-temperature resistance.

A photosensitive resin composition of the invention includes an alkali-soluble resin (A), a polymerizable monomer (B), a thermal acid generator (D), a photoinitiator (E) and a solvent (F). A weight average molecular weight of the alkali-soluble resin (A) is 5,000 to 40,000. The polymerizable monomer (B) includes an epoxy monomer (B1), an ethylenically unsaturated monomer (B2) or the combination thereof. The thermal acid generator (D) includes a hexafluoroonium salt. The epoxy monomer (B1) includes a compound represented by the following Formula (B-1):

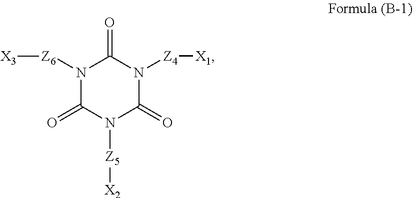

in Formula (B-1), X₁, X₂ and X₃ each include at least one epoxy group, Z₄, Z₅ and Z₆ each indicate an alkylene group having 1 to 6 carbon atoms,

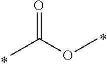

or a combination thereof, X₁, X₂ and X₃ are the same or different, Z₄, Z₅ and Z₆ are the same or different, * indicates a bonding position.

In an embodiment of the invention, in the Formula (B-1), X₁, X₂ and X₃ each indicate

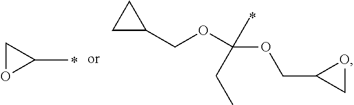

Z₄, Z₅ and Z₆ each indicate an alkylene group having 1 to 6 carbon atoms or

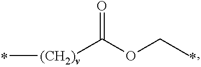

v indicates an integer of 1 to 4, * indicates a bonding position.

In an embodiment of the invention, the epoxy monomer (B1) includes at least one of compounds represented by the following Formula (B-2) to Formula (B-3):

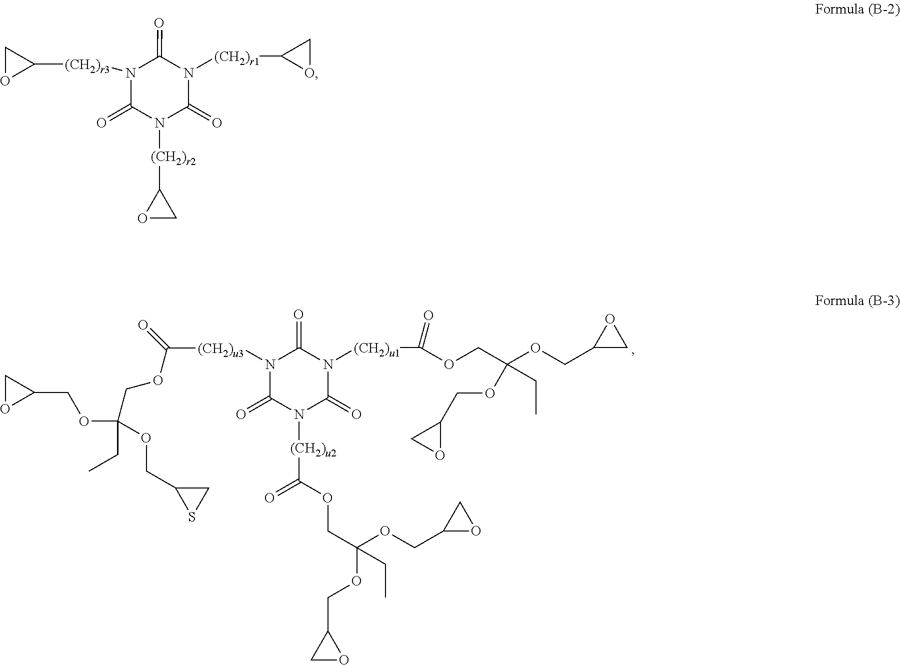

in Formula (B-2) and Formula (B-3), r1 to r3 each indicate an integer of 1 to 6, u1 to u3 each indicate an integer of 1 to 6.

In an embodiment of the invention, the alkali-soluble resin (A) includes at least one of structural units represented by the following Formula (A-1) to Formula (A-4):

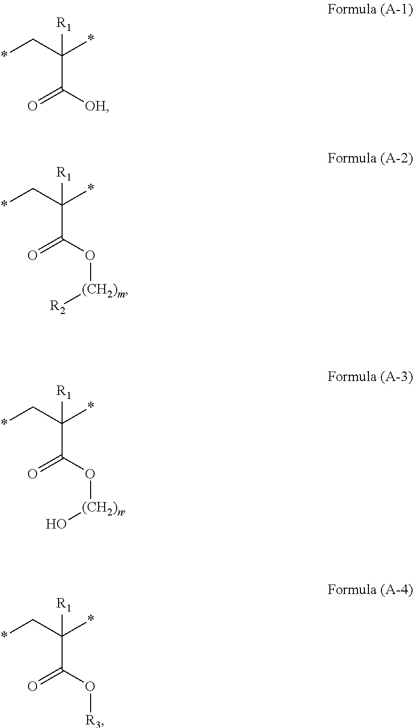

in Formula (A-1) to Formula (A-4), R₁ indicates a hydrogen atom or a methyl group, R₂ indicates a cycloalkyl group having 3 to 6 carbon atoms, R₃ indicates an alkyl group having 1 to 12 carbon atoms, m indicates an integer of 0 to 6, n indicates an integer of 1 to 4, * indicates a bonding position.

In an embodiment of the invention, based on a total usage amount of 100 parts by weight of the photosensitive resin composition, a usage amount of a monomer forming the structural unit represented by Formula (A-1) is 2.7 parts by weight to 16.5 parts by weight, a usage amount of a monomer forming the structural unit represented by Formula (A-2) is 4.1 parts by weight to 12.9 parts by weight, a usage amount of a monomer forming the structural unit represented by Formula (A-3) is 3.3 parts by weight to 16.9 parts by weight, or a usage amount of a monomer forming the structural unit represented by Formula (A-4) is 8.0 parts by weight to 20.0 parts by weight.

In an embodiment of the invention, a number of functional groups of the ethylenically unsaturated monomer (B2) is greater than or equal to 3.

In an embodiment of the invention, the ethylenically unsaturated monomer (B2) includes a compound represented by the following Formula (B-4):

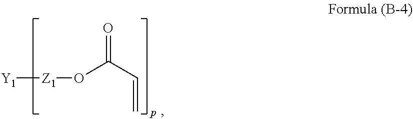

in Formula (B-4), Y₁ indicates an oxygen atom or CR₄, R₄ indicates a hydrogen atom or an alkyl group having 1 to 4 carbon atoms, Z₁ indicates an alkylene group having 1 to 11 carbon atoms, *—OZ₂—* or a combination thereof, Z₂ indicates an alkylene group having 2 to 3 carbon atoms, p indicates 2 or 3, * indicates a bonding position, structures in parentheses are the same or different from each other.

In an embodiment of the invention, the ethylenically unsaturated monomer (B2) includes at least one of compounds represented by the following Formula (B-5) to Formula (B-7):

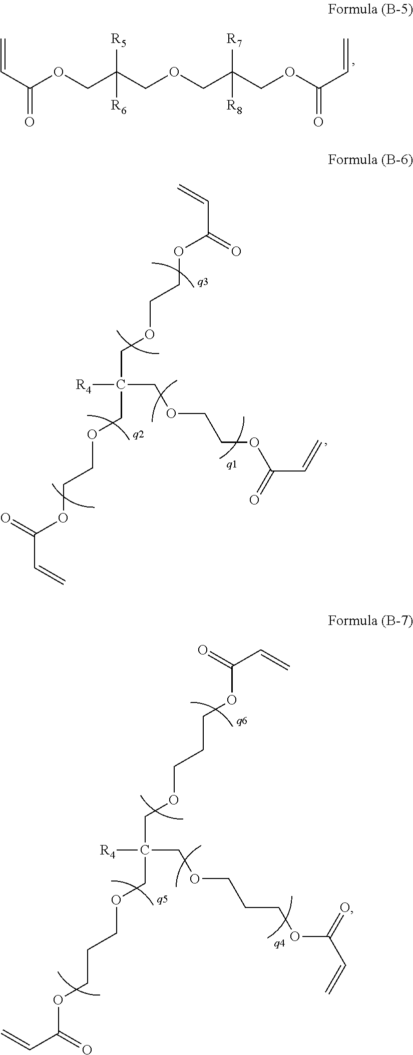

in Formula (B-5) to Formula (B-7), R₄ indicates a hydrogen atom or an alkyl group having 1 to 4 carbon atoms, R₅ to R₈ each indicates a hydrogen atom, an alkyl group having 1 to 4 carbon atoms,

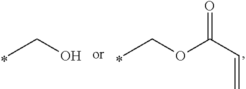

q₁ to q₆ each indicate an integer of 0 to 6, a sum of q₁, q₂ and q₃ is an integer of 0 to 6, a sum of q₄, q₅ and q₆ is an integer of 0 to 6, * indicates a bonding position.

In an embodiment of the invention, the photosensitive resin composition further includes an antioxidant (C). The antioxidant (C) includes a compound represented by the following Formula (C-1):

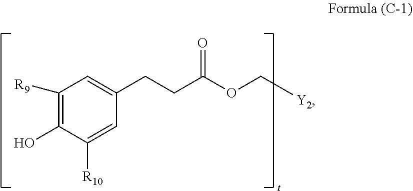

in Formula (C-1), R₉ and R₁₀ each indicate an alkyl group having 1 to 4 carbon atoms,
when t is 2, Y₂ indicates a single bond, a sulfur atom, a methylene group or a combination thereof,
when t is 3, Y₂ indicates a trivalent methyl group,
when t is 4, Y₂ indicates a carbon atom.

In an embodiment of the invention, the thermal acid generator (D) includes a hexafluorophosphate salt.

In an embodiment of the invention, based on a total usage amount of 100 parts by weight of the photosensitive resin composition, a usage amount of the thermal acid generator (D) is 0.1 part by weight to 5.0 parts by weight.

In an embodiment of the invention, the photoinitiator (E) includes a phenylphosphine oxide compound.

In an embodiment of the invention, the solvent (F) includes propylene glycol methyl ether acetate, tetrahydrofuran, chloroform or a combination thereof.

In an embodiment of the invention, the photosensitive resin composition further includes a surfactant (G). The surfactant (G) includes a fluorine-based surfactant.

In an embodiment of the invention, based on a total usage amount of 100 parts by weight of the photosensitive resin composition, a usage amount of the alkali-soluble resin (A) is 13 parts by weight to 50 parts by weight, a usage amount of the polymerizable monomer (B) is 6 parts by weight to 30 parts by weight, a usage amount of the photoinitiator (E) is 0.3 part by weight to 3.3 parts by weight, and a usage amount of the solvent (F) is 18 parts by weight to 65 parts by weight.

A cured product of the invention is formed by curing the photosensitive resin composition above.

In an embodiment of the invention, a thickness of the cured product is 5 μm to 67 μm.

In an embodiment of the invention, a transmittance of the cured product at a wavelength of 400 nm to 1100 nm is greater than or equal to 95%.

In an embodiment of the invention, the cured product has photosensitive properties as follows: x (J/m²) indicates exposure amount, y indicates a ratio (y=Δh/h) of developed residual film thickness Δh (μm) to the coating film thickness h (μm) before development, a relationship between the developed residual film (y) and the exposure amount (x) is y=α·log₁₀(x)±β, and α is 0.4≤α≤0.6.

Based on above, the photosensitive resin composition of the invention includes the epoxy monomer (B1) having a specific structure and the thermal acid generator (D) including a hexafluoroonium salt. Thus, the cured product formed by the photosensitive resin composition has good light transmittance, curvature change rate of developed residual film corresponding to exposure amount, developability, high-temperature resistance and low-temperature resistance, thereby suitable for an optical element.

In order to make the aforementioned features and advantages of the disclosure more comprehensible, embodiments are described in detail below.

### DESCRIPTION OF THE EMBODIMENTS

### Photosensitive Resin Composition

The invention provides a photosensitive resin composition, including an alkali-soluble resin (A), a polymerizable monomer (B), a thermal acid generator (D), a photoinitiator (E) and a solvent (F). In addition, the photosensitive resin composition of the invention may further include an antioxidant (C), a surfactant (G) or other additives as needed. Hereinafter, the various components above are described in detail.

It should be mentioned that, in the following, (meth)acrylic acid represents acrylic acid and/or methacrylic acid, and (meth)acrylate represents acrylate and/or methacrylate.

### Alkali-Soluble Resin (A)

The alkali-soluble resin (A) is not particularly limited, and suitable alkali-soluble resin may be selected according to needs. For example, the alkali-soluble resin (A) may be a single alkali-soluble resin, and may also be a combination of a plurality of alkali-soluble resins. The alkali-soluble resin (A) may further include (meth)acrylic-based resin, epoxy-based resin, styrene-based resin, amide-based resin, amide epoxy-based resin, alkyd-based resin, phenol-based resin or other suitable alkali-soluble resins. The alkali-soluble resin (A) may further include a structural unit composed by styrene, benzyl (meth)acrylate, cyclohexyl (meth)acrylate, phenoxyethyl (meth)acrylate, 2-phenoxyethyl acrylate, 2-hydroxy-3-phenoxypropyl acrylate, 2-acryloyloxyethyl phthalate, 2-acryloyloxy-2-hydroxyethyl phthalate, 2-methylacryloyloxyethyl-2-hydroxypropyl phthalate, methyl (meth)acrylate, ethyl (meth)acrylate, n-propyl (meth)acrylate, isopropyl (meth)acrylate, butyl (meth)acrylate, isobutyl (meth)acrylate, sec-butyl (meth)acrylate, tert-butyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 4-hydroxybutyl (meth)acrylate, 2-ethylhexyl (meth)acrylate, ethylene glycol di(meth)acrylate, glycidyl (meth)acrylate, dimethylaminoethyl (meth)acrylate, diethylaminoethyl (meth)acrylate, tetrahydrofuran methyl (meth)acrylate, epoxypropyl (meth)acrylate, 2,2,2-trifluoroethyl (meth)acrylate, 2,2,3,3-tetrafluoropropyl (meth)acrylate, (meth)acrylic acid, α-bromo(meth)acrylic acid, methylenesuccinic acid (itaconic acid), propynoic acid, cis-butenedioic acid (maleic acid), maleic anhydride, monomethyl maleate, monoethyl maleate, trans-butenedioic acid (fumaric acid) or other suitable monomers.

In the present embodiment, the alkali-soluble resin (A) may include at least one of structural units represented by the following Formula (A-1) to Formula (A-4), preferably includes each of structural units represented by Formula (A-1) to Formula (A-4). The alkali-soluble resin (A) may include a single structural unit or may include a combination of a plurality of structural units. In the present embodiment, a weight average molecular weight of the alkali-soluble resin (A) is 5,000 to 40,000.

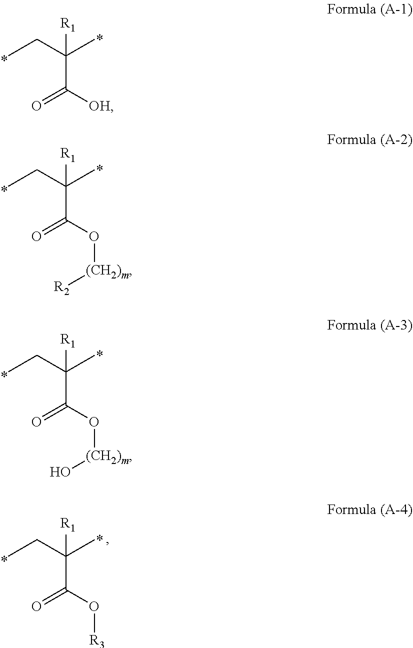

in Formula (A-1) to Formula (A-4), R₁ indicates a hydrogen atom or a methyl group, R₂ indicates a cycloalkyl group having 3 to 6 carbon atoms, R₃ indicates an alkyl group having 1 to 12 carbon atoms, m indicates an integer of 0 to 6, n indicates an integer of 1 to 4, * indicates a bonding position.

In Formula (A-1) to Formula (A-4), R₁ is preferably a methyl group; R₂ is preferably a cyclohexyl group; R₃ is preferably an alkyl group having 1 to 3 carbon atoms, more preferably an alkyl group having 1 to 2 carbon atoms; m is preferably an integer of 0 to 2, more preferably an integer of 0 to 1; n is preferably an integer of 1 to 3, more preferably an integer of 1 to 2.

The preferable specific example of the structural unit represented by Formula (A-1) includes a structural unit represented by the following Formula (a-1):

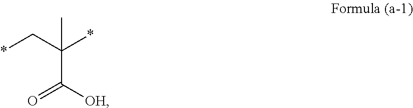

in Formula (a-1), * indicates a bonding position.

The preferable specific example of the structural unit represented by Formula (A-2) includes a structural unit represented by the following Formula (a-2):

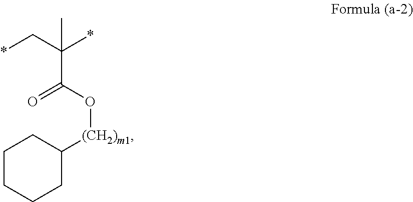

in Formula (a-2), m1 indicates an integer of 0 to 2, * indicates a bonding position.

The preferable specific example of the structural unit represented by Formula (A-3) includes a structural unit represented by the following Formula (a-3):

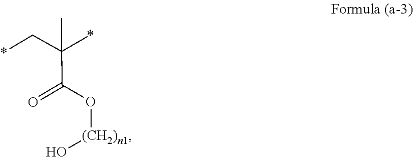

in Formula (a-3), n1 indicates an integer of 1 to 3, * indicates a bonding position.

The preferable specific example of the structural unit represented by Formula (A-4) includes a structural unit represented by the following Formula (a-4):

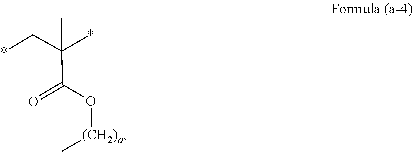

in Formula (a-4), a indicates an integer of 0 to 2, * indicates a bonding position.

The alkali-soluble resin (A) preferably includes at least one of structural units represented by Formula (a-1) to Formula (a-4) above, more preferably includes each of structural units represented by Formula (a-1) to Formula (a-4).

Based on a total usage amount of 100 parts by weight of the photosensitive resin composition, a usage amount of a monomer forming the structural unit represented by Formula (A-1) is 2.7 parts by weight to 16.5 parts by weight, preferably 7.1 parts by weight to 7.6 parts by weight; a usage amount of a monomer forming the structural unit represented by Formula (A-2) is 4.1 parts by weight to 12.9 parts by weight, preferably 7.4 parts by weight to 8.2 parts by weight; a usage amount of a monomer forming the structural unit represented by Formula (A-3) is 3.3 parts by weight to 16.9 parts by weight, preferably 8.5 parts by weight to 9.0 parts by weight; or a usage amount of a monomer forming the structural unit represented by Formula (A-4) is 8.0 parts by weight to 20.0 parts by weight, preferably 12.2 parts by weight to 13.0 parts by weight.

Based on a total usage amount of 100 parts by weight of the photosensitive resin composition, a usage amount of the alkali-soluble resin (A) is 13 parts by weight to 50 parts by weight, preferably 35 parts by weight to 38 parts by weight.

### Polymerizable Monomer (B)

The polymerizable monomer (B) includes an epoxy monomer (B1), an ethylenically unsaturated monomer (B2) or the combination thereof. In the present embodiment, the epoxy monomer (B1) includes a compound represented by the following Formula (B-1), a number of functional groups of the ethylenically unsaturated monomer (B2) may be greater than or equal to 3. The “number of functional groups” means the number of functional groups in the ethylenically unsaturated monomer (B2), wherein the functional group includes

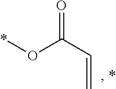 [SMILES: *OC(=O)C=C]

indicates a bonding position.

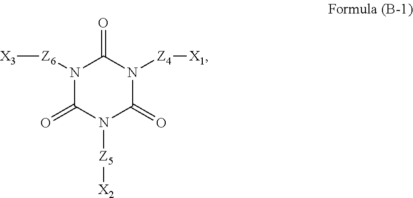

in Formula (B-1), X₁, X₂ and X₃ each include at least one epoxy group, Z₄, Z₅ and Z₆ each indicate an alkylene group having 1 to 6 carbon atoms,

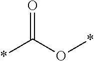 [SMILES: *OC(*)=O]

or a combination thereof, X₁, X₂ and X₃ are the same or different, Z₄, Z₅ and Z₆ are the same or different, * indicates a bonding position.

In Formula (B-1), X₁, X₂ and X₃ each preferably indicate

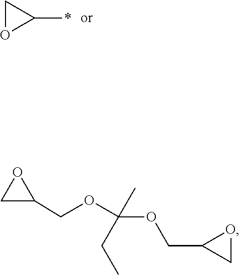

Z₄, Z₅ and Z₆ each preferably indicate an alkylene group having 1 to 6 carbon atoms or

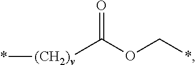

v indicates an integer of 1 to 4, * indicates a bonding position.

In the present embodiment, the epoxy monomer (B1) may include at least one of compounds represented by the following Formula (B-2) to Formula (B-3).

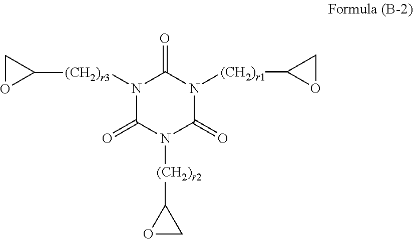

In Formula (B-2), r1 to r3 each indicate an integer of 1 to 6, preferably an integer of 4 to 6.

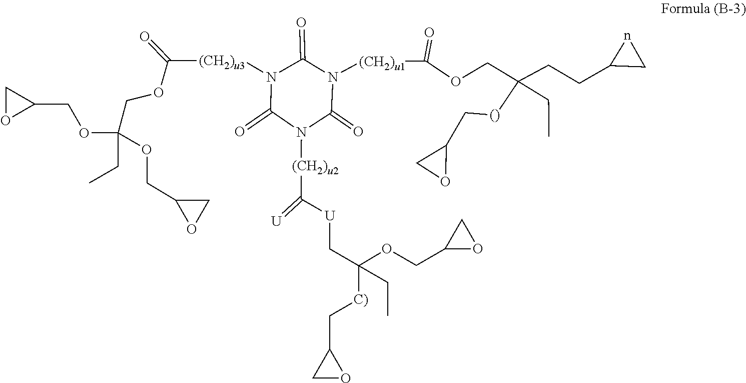

In Formula (B-3), u1 to u3 each indicate an integer of 1 to 6, preferably an integer of 4 to 6.

For example, the epoxy monomer (B1) may further include acrylic epoxy ester-based compound, epoxy ester-based compound, cyanuric epoxy ester-based compound, silyl epoxy ester-based compound, phenyl epoxy ester-based compound or other suitable epoxy monomers. The epoxy monomer (B1) may be used alone or in combination. In the present embodiment, the epoxy monomer (B1) is preferably cyanuric epoxy ester-based compound.

For example, the ethylenically unsaturated monomer (B2) may include polyfunctional urethane acrylate, ethylene glycol di(meth)acrylate, diethylene glycol di(meth)acrylate, propylene glycol di(meth)acrylate, polypropylene glycol di(meth)acrylate, butanediol di(meth)acrylate, neopentyl glycol di(meth)acrylate, 1,6-hexanediol di(meth)acrylate, dipentaerythritol pentaacrylate, pentaerythritol tri(meth)acrylate, pentaerythritol tetra(meth)acrylate, dipentaerythritol penta(meth)acrylate, dipentaerythritol hexa(meth)acrylate, 2,2-bis(4-(meth)acryloyloxy diethoxyphenyl)propane, 2,2-bis(4-(meth)acryloyloxy polyethoxyphenyl) propane, ethylene glycol diglycidyl ether di(meth)acrylate, diethylene glycol diglycidyl ether di(meth)acrylate, glycerol triacrylate, trimethylolpropane tri(meth)acrylate, glycerol di(meth)acrylate, pentaerythritol triacrylate, pentaerythritol tetraacrylate, glycerol polyglycidyl ether poly(meth)acrylate, urethane (meth)acrylate, a product of trimethylhexamethylene diisocyanate, hexamethylene diisocyanate and 2-hydroxyethyl (meth)acrylate, methylene bis(meth)acrylamide, condensate of polyol and N-methylol(meth)acrylamide, pentaerythritol penta(meth)acrylate or other suitable ethylenically unsaturated monomers. The ethylenically unsaturated monomer (B2) may be used alone or in combination. In the present embodiment, the ethylenically unsaturated monomer (B2) is preferably dipentaerythritol hexaacrylate.

In the present embodiment, the ethylenically unsaturated monomer (B2) may include a compound represented by the following Formula (B-4):

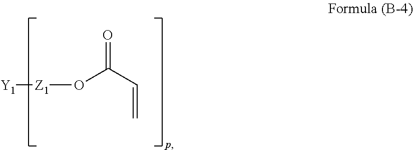

in Formula (B-4), Y₁ indicates an oxygen atom or CR₄, R₄ indicates a hydrogen atom or an alkyl group having 1 to 4 carbon atoms, Z₁ indicates an alkylene group having 1 to 11 carbon atoms, *—OZ₂—* or a combination thereof, Z₂ indicates an alkylene group having 2 to 3 carbon atoms, p indicates 2 or 3, * indicates a bonding position, structures in parentheses are the same or different from each other.

In Formula (B-4), when p is 2, Y₁ indicates an oxygen atom; when p is 3, Y₁ indicates CR₄; Z₁ is preferably an alkylene group having 1 to 11 carbon atoms, an alkylene group substituted by

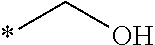 [SMILES: *CO]

and having 1 to 11 carbon atoms, an alkylene group substituted by

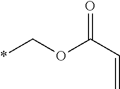 [SMILES: *COC(=O)C=C]

and having 1 to 11 carbon atoms, *—OZ₂—* or a combination thereof, more preferably an alkylene group having 1 to 3 carbon atoms, an alkylene group substituted by

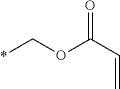 [SMILES: *COC(=O)C=C]

and having 3 to 7 carbon atoms, *—OZ₂—* or a combination thereof, much more preferably

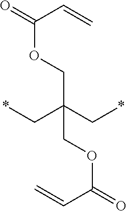 [SMILES: *CC(C*)(COC(=O)C=C)COC(=O)C=C]

or *—CH₂—(OZ₂)_{q}—*, wherein q indicates an integer of 0 to 6, each of q may be the same or different from each other and a sum of each q is an integer of 0 to 6. For example, when structures in parentheses in Formula (B-4) are different from each other and Z₁ is *—CH₂—(OZ₂)_{q}—*, each of q may be the same or different from each other and the sum of each q is an integer of 0 to 6.

In the present embodiment, the ethylenically unsaturated monomer (B2) may include at least one of compounds represented by the following Formula (B-5) to Formula (B-7).

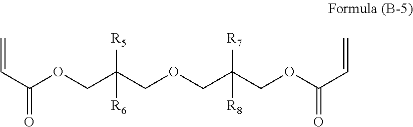

In Formula (B-5), R₅ to R₈ each indicate a hydrogen atom, an alkyl group having 1 to 4 carbon atoms,

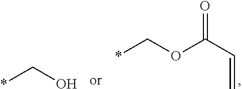

* indicates a bonding position; preferably

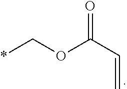 [SMILES: *COC(=O)C=C]

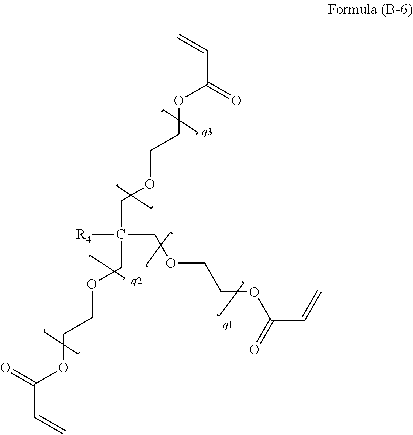

In Formula (B-6), R₄ indicates a hydrogen atom or an alkyl group having 1 to 4 carbon atoms, preferably an alkyl group having 1 to 2 carbon atoms; q₁ to q₃ each indicate an integer of 0 to 6, a sum of q₁, q₂ and q₃ is an integer of 0 to 6, each q₁, q₂ and q₃ is preferably an integer of 1 to 2.

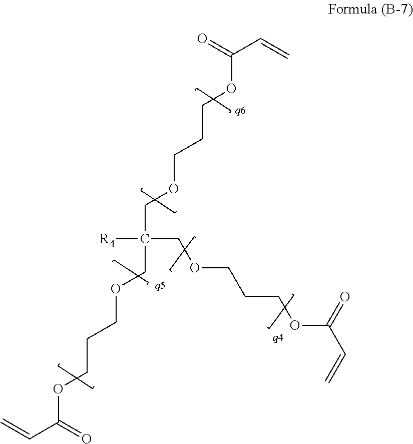

In Formula (B-7), R₄ indicates a hydrogen atom or an alkyl group having 1 to 4 carbon atoms, preferably an alkyl group having 1 to 2 carbon atoms; q₄ to q₆ each indicate an integer of 0 to 6, a sum of q₄, q₅ and q₆ is an integer of 0 to 6, each q₄, q₅ and q₆ is preferably an integer of 1 to 2.

Based on a total usage amount of 100 parts by weight of the photosensitive resin composition, a usage amount of the polymerizable monomer (B) is 6 parts by weight to 30 parts by weight, preferably 11 parts by weight to 12 parts by weight.

When the polymerizable monomer (B) in the photosensitive resin composition includes an epoxy monomer (B1), an ethylenically unsaturated monomer (B2) or the combination thereof, the cured product formed by the photosensitive resin composition has good high-temperature resistance and low-temperature resistance.

### Antioxidant (C)

The antioxidant (C) is not particularly limited, and suitable antioxidant may be selected according to needs. For example, the antioxidant (C) may include di[3-(1,1-dimethylethyl)-4-hydroxy-5-methylphenylpropionic acid]tripolyethylene glycol, tetrakis(3,5-di-tert-butyl-4-hydroxy) pentaerythritol phenylpropionate, β-(3,5-di-tert-butyl-4-hydroxyphenyl) isooctyl alcohol propionate, 3-(3,5-di-tert-butyl-4-hydroxyphenyl) n-octadecyl propionate, 2,4,6-trioxo-1,3,5-triazine-1,3,5(2H,4H,6H)triyltri(2,1-ethylenediyl)tri(3,5-di-tert-butyl-4-hydroxyphenyl)propionate], 2,6-di-tert-butyl-p-cresol, 4-[(4,6-dioctylthio-1,3,5-triazin-2-yl)amino]-2,6-di(1,1-methylethyl)phenol, 1,3,5-trimethyl-2,4,6-tris(3,5-di-tert-butyl-4-hydroxybenzyl)benzene, 1,3,5-tris(3,5-di-tert-butyl-4-hydroxybenzyl)-1,3,5-triazine-2,4,6(1H, 3H,5H)-trione, 1,3,5-tris[[4-(1,1-dimethylethyl)-3-hydroxy-2,6-dimethylphenyl]methyl]-1,3,5-triazine-2,4,6-trione, 2-acrylic acid-2-(1,1-dimethylethyl)-6-[[3-(1,1-dimethylethyl)-2-hydroxy-5-methylphenyl]methyl]-4-tolyl ester, 2-methyl-4,6-di[(octylthio)methyl]phenol, N,N′-bis-(3-(3,5-di-tert-butyl-4-hydroxyphenyl) propionyl)hexamethylenediamine, N,N′-bis[3-(3,5-di-tert-butyl-4-hydroxyphenyl)propionyl] hydrazine, 1,1,3-tris(2-methyl-4-hydroxy-5-tert-butylphenyl)butane, di[3,5-di-(1,1-dimethylethyl)-4-hydroxy-]thiadiglycol phenylpropionate, 2,4-di(dodecylthiomethyl)-6-methylphenol, 3,5-di(1,1-dimethylethyl)-4-hydroxy-C7-9-branched chain alkyl phenylpropionate, 4,4′-thiobis(6-tert-butyl-m-cresol), tris(2,4-di-tert-butyl)phenyl phosphite, tris(dodecyl) phosphite, pentaerythritol diisodecyl diphosphite, poly(dipropyleneglycol) phenyl phosphite, tris(dipropyleneglycol)phosphite, didodecyl 3,3′-thiodipropionate, dioctadecyl 3,3′-thiodipropionate or other suitable antioxidants. The antioxidant (C) may be used alone or in combination. In the present embodiment, the antioxidant (C) is preferably tetrakis(3,5-di-tert-butyl-4-hydroxy) pentaerythritol phenylpropionate.

In the present embodiment, the antioxidant (C) may include a compound represented by the following Formula (C-1):

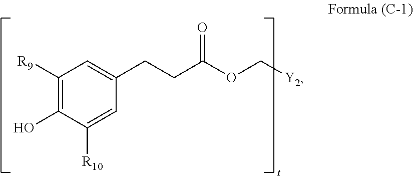

in Formula (C-1), R₉ and R₁₀ each indicate an alkyl group having 1 to 4 carbon atoms,
when t is 2, Y₂ indicates a single bond, a sulfur atom, a methylene group or a combination thereof,
when t is 3, Y₂ indicates a trivalent methyl group,
when t is 4, Y₂ indicates a carbon atom.

In Formula (C-1), R₉ and R₁₀ are preferably an alkyl group having 4 carbon atoms, more preferably tert-butyl group. When t is 2, Y₂ is preferably methylene group.

Based on a total usage amount of 100 parts by weight of the photosensitive resin composition, a usage amount of the antioxidant (C) is 0.5 part by weight to 9.0 parts by weight, preferably 1.5 parts by weight to 9.0 parts by weight.

When the photosensitive resin composition includes the antioxidant (C), the cured product formed by the photosensitive resin composition has good light transmittance.

### Thermal Acid Generator (D)

The thermal acid generator (D) includes a hexafluoroonium salt or other suitable thermal acid generators, preferably hexafluoroonium salt. The thermal acid generator (D) may be used alone or in combination.

For example, the hexafluoroonium salt may include hexafluoroantimony salt, hexafluorophosphate salt or other suitable hexafluoroonium salts. In the present embodiment, the hexafluoroonium salt is preferably hexafluorophosphate salt.

For example, the hexafluoroonium salt may include triarylsulfonium hexafluoroantimonate salt, bis(4-tert-butylphenyl)iodonium hexafluorophosphate salt, (4-methylphenyl) [4-(2-methylpropyl)phenyl] iodonium hexafluorophosphate salt, diaryliodonium hexafluorophosphate salt (e.g. bis(4-methylphenyl)iodonium hexafluorophosphate salt), 4-isopropyl-4′-methyldiphenyl iodide tetrakis(pentafluorophenyl) borate salt, (sulfo-di-4,1-phenylene)diphenylsulfonium hexafluorophosphate salt, [(phenylthiol)phenyl]diphenylsulfonium hexafluorophosphate(1-) salt, diphenyl[4-(phenylthio)phenyl]sulfonium hexafluoroantimonate salt or other suitable hexafluoroonium salts. The hexafluoroonium salt is preferably bis(4-tert-butylphenyl)iodonium hexafluorophosphate salt, (4-methylphenyl) [4-(2-methylpropyl)phenyl] iodonium hexafluorophosphate salt, diaryliodonium hexafluorophosphate salt (e.g. bis(4-methylphenyl)iodonium hexafluorophosphate salt), (sulfo-di-4,1-phenylene)diphenylsulfonium hexafluorophosphate salt. The hexafluoroonium salt may be used alone or in combination.

Based on a total usage amount of 100 parts by weight of the photosensitive resin composition, a usage amount of the thermal acid generator (D) is 0.1 part by weight to 5.0 parts by weight, preferably 0.3 part by weight to 3.0 parts by weight.

When the photosensitive resin composition includes the thermal acid generator (D), the cured product formed by the photosensitive resin composition has good high-temperature resistance or low-temperature resistance. At the same time, when the thermal acid generator (D) includes the hexafluorophosphate salt, the cured product formed by the photosensitive resin composition has better light transmittance, high-temperature resistance and low-temperature resistance.

### Photoinitiator (E)

The photoinitiator (E) is not particularly limited, and suitable photoinitiator may be selected according to needs. For example, the photoinitiator (E) may include at least one of compounds selected from the group consisting of aromatic ketone-based compound, quinone-based compound, benzoin ether-based compound, benzoin-based compounds, diphenylethanedione-based compound, acridine-based compound, coumarin-based compound, acylphosphine oxide-based compound, acetophenone-based compound, dialkylbenzophenone-based compound, oxime ester-based compound, hexaarylimidazole-based compound. In the present embodiment, the photoinitiator (E) is preferably acylphosphine oxide-based compound, more preferably phenylphosphine oxide compound. However, the invention is not limited thereto, and the photoinitiator (E) may include other suitable photoinitiators.

For example, the photoinitiator (E) may include 1-hydroxycyclohexyl phenyl ketone, 2,2-dimethoxy-1,2-diphenyl-1-ethanone, 2-methyl-1-(4-methylthiophenyl)-2-morpholinyl-1-propanone, 2-benzyl-2-methylamino-1-(4-morpholinylphenyl)-1-butanone, 2-hydroxy-2-methyl-1-phenyl-1-propanone, 2,4,6-trimethylbenzoyl-diphenylphosphine oxide, phenylbis(2,4,6-trimethylbenzoyl)phosphine oxide, 2-hydroxyl-2-methyl-1-[4-(2-hydroxyethoxy)phenyl]-1-propanone, 2,4-diethylthioxanthone, 2-chlorothioxanthone, 2,4-dimethylthioxanthone, 1-chloro-4-propoxythioxanthone, 1-(4-isopropylphenyl)-2-hydroxy-2-methyl-1-propanone, 1-(4-laurylphenyl)-2-hydroxy-2-methylpropan-1-one, p-dimethylaminoethyl benzoate, 4-dimethylaminobenzoic acid, 4-dimethylaminomethyl benzoate, 4-dimethylaminoethyl benzoate, 4-dimethylaminobenzoic acid-2-ethylhexyl ester, 4-dimethylaminobenzoic acid-2-isoamyl ester, 2,2-diethoxyacetophenone, methyl o-benzoylbenzoate, 4,4′-bis(dimethylamino)benzophenone, p-dimethylaminoacetophenone, thioxanthone, 2-methyl thioxanthone, 2-isopropyl thioxanthone, dibenzocycloheptanone, 2,2-dichloro-4-phenoxy acetophenone, 4-(dimethylamino)amyl benzoate, benzophenone, 4,4′-bis(diethylamino) benzophenone, 3,3′-dimethyl-4-methoxybenzophenone, 4,4′-dichlorobenzophenone, 2-benzyl-2-dimethylamino-1-(4-morpholinophenyl)-butanone, 2-ethylanthraquinone, phenanthraquinone, 2-tert-butylanthraquinone, 1,2-benzoanthraquinone, 2-phenylanthraquinone, 1-chloroanthraquinone, 2-methylanthraquinone, 1,4-naphthoquinone, 2,3-dimethylanthraquinone, benzoin methyl ether, benzoin ethyl ether, benzoin isopropyl ether, benzoin n-butyl ether, benzoin isobutyl ether, benzoin, benzophenone dimethyl ketal, 9-phenylacridine, 1,7-bis(9-acridinyl)heptane or other suitable photoinitiators. The photoinitiator (E) may be used alone or in combination. In the present embodiment, the photoinitiator (E) is preferably 2,4,6-trimethylbenzoyl-diphenylphosphine oxide.

Based on a total usage amount of 100 parts by weight of the photosensitive resin composition, a usage amount of the photoinitiator (E) is 0.3 part by weight to 3.3 parts by weight, preferably 0.9 part by weight to 1.0 part by weight.

### Solvent (F)

The solvent (F) is not particularly limited, and suitable solvent may be selected according to needs. For example, the solvent (F) may include tetrahydrofuran, hexane, heptane, octane, decane, benzene, toluene, xylene, mesitylene, tetramethylbenzene, benzyl alcohol, methyl ethyl ketone, acetone, methyl isobutyl ketone, cyclohexanone, methanol, ethanol, propanol, butanol, hexanol, cyclohexanol, ethylene glycol, diethylene glycol, glycerol, ethylene glycol monomethyl ether, ethylene glycol monoethyl ether, propylene glycol monomethyl ether, propylene glycol monoethyl ether, diethylene glycol monomethyl ether, diethylene glycol monoethyl ether, diethylene glycol dimethyl ether, diethylene glycol diethyl ether, 2-methoxy butyl acetate, 3-methoxybutyl acetate, 4-methoxybutyl acetate, 2-methyl-3-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, methyl lactate, ethyl lactate, methyl acetate, ethyl acetate, propyl acetate, butyl acetate, ethylene glycol ether acetate, diethylene glycol ether acetate, propylene glycol methyl ether acetate (PGMEA), propylene glycol monoethyl ether acetate, methyl propionate, ethyl propionate, ethyl benzoate, propyl benzoate, butyl benzoate, methyl butanoate, ethyl butanoate, propyl butanoate, chloroform or other suitable solvents. The solvent (F) may be used alone or in combination. In the present embodiment, the solvent (F) is preferably propylene glycol methyl ether acetate, tetrahydrofuran, chloroform or a combination thereof.

Based on a total usage amount of 100 parts by weight of the photosensitive resin composition, a usage amount of the solvent (F) is 18 parts by weight to 65 parts by weight, preferably 49 parts by weight to 50 parts by weight.

When the photosensitive resin composition includes the solvent (F), the photosensitive resin composition has an appropriate viscosity, thereby having good coating uniformity to form the cured product.

### Surfactant (G)

The surfactant (G) is not particularly limited, and suitable surfactant may be selected according to needs. For example, the surfactant (G) may include fluorine-based surfactant, siloxane-based surfactant, alkali metal alkyl sulfate-based surfactant, alkyl sulfonate-based surfactant, alkyl aryl sulfonate-based surfactant, high alkyl naphthalene sulfonate-based surfactant, polyoxyethylene alkyl ether-based surfactant or other suitable surfactants. The surfactant (G) may be used alone or in combination. In the present embodiment, the surfactant (G) is preferably fluorine-based surfactant.

Based on a total usage amount of 100 parts by weight of the photosensitive resin composition, a usage amount of the surfactant (G) is 0.01 part by weight to 0.1 part by weight.

### Preparation Method of Photosensitive Resin Composition

The preparation method of the photosensitive resin composition is not particularly limited. For example, the alkali-soluble resin (A), the polymerizable monomer (B), the thermal acid generator (D), the photoinitiator (E) and the solvent (F) were placed in a stirrer and stirred to be uniformly mixed into a solution state. If needed, the antioxidant (C), the surfactant (G) and other additives may also be added, and after mixing uniformly, a liquid photosensitive resin composition was obtained.

### Manufacturing Method of Cured Product

An exemplary embodiment of the invention provides a cured product, which is formed by using the above photosensitive resin composition.

The cured product may be formed by coating the photosensitive resin composition on a substrate to form a coating film and performing pre-bake, exposure, development, and post-bake on the coating film. For example, after the photosensitive resin composition was coated on the substrate to form a coating film, the baking step before the exposure (i.e. pre-bake) was performed at a temperature of 90° C. for 5 minutes. Next, the pre-baked coating film was exposed with light of 400 to 5200 J/m² using a stepper. Then, the exposed coating film was performed with a step of development for 200 seconds. Next, developed coating film was washed with distilled water and nitrogen gas was blown to dry the coating film. Then, post-bake was performed at 220° C. for 20 minutes to form a cured product with a thickness of 5 μm to 67 μm on the substrate.

The substrate may be a glass substrate, a plastic base material (such as a polyether sulfone (PES) board, a polycarbonate (PC) board or a polyimide (PI) film) or other transparent substrates, and the type thereof is not particularly limited.

The coating method is not particularly limited, but a spray coating method, a roll coating method, a spin coating method, or the like may be used, and in general, a spin coating method is widely used. In addition, a coating film was formed, and then, in some cases, the residual solvent may be partially removed under reduced pressure.

The developing solution is not particularly limited, and a suitable developing solution may be selected according to needs. For example, the developing solution may be tetramethylazanium hydroxide (TMAH) solution, and the concentration thereof may be 0.3 wt %.

In the present embodiment, a transmittance of the cured product with a thickness of 5 μm to 67 μm at a wavelength of 400 nm to 1100 nm is greater than or equal to 95%. The cured product has photosensitive properties as follows: x (J/m²) indicates exposure amount, y indicates a ratio (y=Δh/h) of developed residual film thickness Δh (μm) to the coating film thickness h (μm) before development, a relationship between the developed residual film (y) and the exposure amount (x) is y=α·log₁₀(x)±β, and α is 0.4≤α≤0.6, β is any real number.

Hereinafter, the invention is described in detail with reference to examples. The following examples are provided to describe the invention, and the scope of the invention includes the scope in the following patent application and its substitutes and modifications, and is not limited to the scope of the examples.

### Examples of Photosensitive Resin Composition and Cured Product

Example 1 to Example 5 and Comparative example 1 to Comparative example 3 of the photosensitive resin composition and the cured product are described below:

### Example 1

### a. Photosensitive Resin Composition

7.46 parts by weight of monomer forming structural unit represented by Formula (a-1), 8.18 parts by weight of monomer forming structural unit represented by Formula (a-2), 8.89 parts by weight of monomer forming structural unit represented by Formula (a-3), 12.81 parts by weight of monomer forming structural unit represented by Formula (a-4), 5.96 parts by weight of compound represented by Formula (B-2), 5.96 parts by weight of dipentaerythritol hexaacrylate, 0.3 part by weight of thermal acid generator (D-1), and 0.95 part by weight of 2,4,6-trimethylbenzoyl-diphenylphosphine oxide were added to 49.49 parts by weight of propylene glycol methyl ether acetate (PGMEA), and after stirring uniformly with a stirrer, the photosensitive resin composition of Example 1 was obtained.

### b. Cured Product

Each photosensitive resin composition prepared in the Examples was coated on a substrate by a spin coating method (spin coater model: MK-VIII, manufactured by Tokyo Electron Limited (TEL), rotation speed: about 1000 rpm). Next, pre-bake was performed at a temperature of 90° C. for 5 minutes to form a film. Then, exposure to the pre-baked film was performed at 400 to 5200 J/m² using a stepper (model: 5500iZa, manufactured by Canon Inc.) to form a semi-finished product. Next, development was performed at a temperature of 23° C. using tetramethylazanium hydroxide solution having a concentration of 0.3 wt % as a developing solution for 200 seconds. Then, the developed coating film was washed with distilled water and nitrogen gas was blown to dry the coating film. Next, post-bake was performed at 220° C. for 20 minutes to obtain a cured product having a pattern thickness of 30 μm. The obtained cured products were evaluated by each of the following evaluation methods, and the results thereof are as shown in Table 2.

### Example 2 to Example 5 and Comparative Example 1 to Comparative Example 3

The photosensitive resin compositions of Example 2 to Example 5 and Comparative example 1 to Comparative example 3 were prepared using the same steps as Example 1, and the difference thereof is: the type and the usage amount of the components of the photosensitive resin compositions were changed (as shown in Table 2), wherein the components/compounds corresponding to the symbols in Table 2 are shown in Table 1. The obtained photosensitive resin compositions were made into cured products and evaluated by each of the following evaluation methods, and the results thereof are as shown in Table 2.

TABLE 1

| | Symbol | Components/compound |
|---|---|---|
| Alkali-soluble | A-1 | Monomer forming structural unit represented by Formula (a-1) |
| resin (A) | A-2 | Monomer forming structural unit represented by Formula (a-2) |
| | A-3 | Monomer forming structural unit represented by Formula (a-3) |
| | A-4 | Monomer forming structural unit represented by Formula (a-4) |
| Polymerizable | B-1 | Compound represented by Formula (B-2), wherein r1 to r3 |
| monomer (B) | | each indicate an integer of 4 to 6. |
| | B-2 | Dipentaerythritol hexaacrylate |
| | B-3 | Compound represented by Formula (B-8) |
| | | 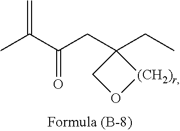 |
| | | wherein r indicates |
| | | an integer of 1 to 3. |
| Thermal acid generator (D) | D-1 | 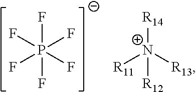 |
| | | wherein R₁₁ to R₁₄ each indicate |
| | | a hydrogen atom or an alkyl group. |
| | D-2 | 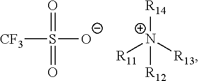 |
| | | wherein R₁₁ to R₁₄ each indicate |
| | | a hydrogen atom or an alkyl group. |
| Photoinitiator (E) | E-1 | 2,4,6-Trimethylbenzoyl-diphenylphosphine oxide |
| | | 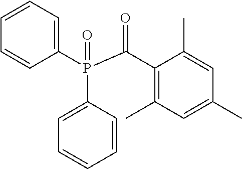 [SMILES: Cc1cc(C)c(C(=O)P(=O)(c2ccccc2)c2ccccc2)c(C)c1] |
| Solvent (F) | F-1 | Propylene glycol methyl ether acetate |

TABLE 2

| | | | | | | | Comparative | | |
|---|---|---|---|---|---|---|---|---|---|
| Component | | Examples | | | | | examples | | |
| (unit: parts by weight) | | 1 | 2 | 3 | 4 | 5 | 1 | 2 | 3 |
| Alkali-soluble | A-1 | 7.46 | 7.51 | 7.54 | 7.14 | 7.52 | 7.54 | 7.71 | 7.71 |
| resin (A) | A-2 | 8.18 | 7.86 | 7.90 | 7.48 | 7.93 | 7.90 | 8.08 | 8.08 |
| | A-3 | 8.89 | 8.94 | 8.98 | 8.50 | 8.97 | 8.98 | 9.19 | 9.19 |
| | A-4 | 12.81 | 12.87 | 12.92 | 12.23 | 12.91 | 12.92 | 13.21 | 13.21 |
| Polymerizable | B-1 | 5.96 | 5.94 | 6.56 | 5.63 | 4.77 | 5.96 | 5.24 | — |
| monomer (B) | B-2 | 5.96 | 5.94 | 5.36 | 5.63 | 7.16 | 5.96 | 5.24 | 5.24 |
| | B-3 | — | — | — | — | — | — | — | 5.24 |
| Thermal acid | D-1 | 0.3 | 0.5 | 0.3 | 3.0 | 0.3 | — | — | — |
| generator (D) | D-2 | — | — | — | — | — | 0.3 | — | — |
| Photoinitiator | E-1 | 0.95 | 0.95 | 0.95 | 0.90 | 0.95 | 0.95 | 0.84 | 0.84 |
| (E) | | | | | | | | | |
| Solvent (F) | F-1 | 49.49 | 49.49 | 49.49 | 49.49 | 49.49 | 49.49 | 50.49 | 50.49 |
| Evaluation | Light | ⊚ | ⊚ | ⊚ | ⊚ | ⊚ | Δ | ⊚ | ⊚ |
| results | transmittance | | | | | | | | |
| | Curvature | ⊚ | ⊚ | ⊚ | ⊚ | ⊚ | ⊚ | ⊚ | ⊚ |
| | change rate | | | | | | | | |
| | Developability | ⊚ | ⊚ | ⊚ | ⊚ | ⊚ | ⊚ | ⊚ | ⊚ |
| | High- | ⊚ | ⊚ | ⊚ | ⊚ | ⊚ | X | Δ | ⊚ |
| | temperature | | | | | | | | |
| | resistance | | | | | | | | |
| | Low- | ⊚ | ⊚ | ⊚ | ⊚ | ⊚ | Δ | X | X |
| | temperature | | | | | | | | |
| | resistance | | | | | | | | |

### Evaluation Methods

### a. Light Transmittance

The prepared cured product (thickness: 30 μm; exposure wavelength: 365 nm) was measured for transmittance at a wavelength of 400 nm to 1100 nm via a UV-Vis Spectrometer (model: U2900, manufactured by HITACHI Co., Ltd.). When the transmittance is higher, the cured product has good light transmittance.

The evaluation criteria of light transmittance are as follows:
⊚: 95%≤transmittance;
Δ: 85%≤transmittance<95%;
X: transmittance<85%.

### b. Curvature Change Rate

The film thickness change during the production process of the three-dimensional micro-molded body (cured product) obtained from the above-mentioned photosensitive resin composition was measured, and the relationship between the film thickness change and the exposure amount was obtained: logarithmize the exposure amount x (J/m²), at the same time, the thickness of the cured product relative to the exposure amount x is represented by the ratio (y=Δh/h) of the developed residual film thickness Δh (μm) to the coating film thickness h (μm) before development. Making a graph with the developed residual film (y) corresponding to the logarithmic exposure amount (log₁₀(x)), the relationship between the developed residual film (y) and the exposure amount (x) is y=α·log₁₀(x)±β. The curvature change rate of the developed residual film (y) corresponding to the exposure amount (x) is evaluated by the α value.

The evaluation criteria of curvature change rate are as follows:
⊚: 0.4≤α≤0.6;
X: α is not within the above range.

### c. Developability

The prepared cured product (thickness: 30 μm) was observed whether the photosensitive resin composition remains at the edge of the pattern on the substrate via a Field Emission Scanning Electron Microscope (Model: SU8010, manufactured by Hitachi Co., Ltd.) at a magnification of 1200× to evaluate developability. When the residue was less, the cured product has good developability.

The evaluation criteria of developability are as follows:
⊚: no photosensitive resin composition residue at the edge of the pattern on the substrate;
X: photosensitive resin composition residue at the edge of the pattern on the substrate.

### d. High-Temperature Resistance

The prepared cured product (thickness: 30 μm) was placed in an environment of 125° C. for 1000 hours. Then, the transmittance was measured at a wavelength of 400 nm to 1100 nm via a UV-Vis Spectrometer (model: U2900, manufactured by HITACHI Co., Ltd.). When the transmittance is higher, the cured product has good high-temperature resistance.

The evaluation criteria of high-temperature resistance are as follows:
⊚: 90%≤transmittance;
Δ: 85%≤transmittance<90%;
X: transmittance<85%.

### e. Low-Temperature Resistance

The prepared cured product (thickness: 30 μm) was placed in an environment of −40° C. for 1000 hours. Then, it was observed whether there was a crack on the surface of the pattern and whether the pattern was peeled off from the substrate via an optical microscope (manufactured by Olympus Corporation) at a magnification of 100×. When the pattern surface is more complete, the cured product has good low-temperature resistance.

The evaluation criteria of low-temperature resistance are as follows:
⊚: no cracks on the surface of the pattern, and no peeling from the substrate;
Δ: crack on the surface of the pattern, and no peeling from the substrate;
X: peeling from the substrate.

### Evaluation Results

As may be seen from Table 2, the cured product formed by the photosensitive resin composition including the epoxy monomer (B1) having a specific structure and the thermal acid generator (D) including a hexafluoroonium salt (Examples 1 to 5) have good light transmittance, curvature change rate of developed residual film corresponding to exposure amount, developability, high-temperature resistance and low-temperature resistance, and may be suitable for an optical element. On the other hand, the light transmittance, high-temperature resistance or low-temperature resistance of the cured product formed by the photosensitive resin composition which does not include the epoxy monomer (B1) having a specific structure or the thermal acid generator (D) including a hexafluoroonium salt (Comparative examples 1 to 3) is not good.

In addition, compared to the cured product (Comparative example 1) prepared by the photosensitive resin composition in which the thermal acid generator (D) does not include a hexafluoroonium salt, the cured products (Examples 1 to 5) prepared by the photosensitive resin composition in which the thermal acid generator (D) includes a hexafluoroonium salt have better light transmittance, high-temperature resistance and low-temperature resistance. Therefore, when the thermal acid generator (D) includes a hexafluoroonium salt, the cured product formed by the photosensitive resin composition may have better light transmittance, high-temperature resistance and low-temperature resistance.

In addition, compared to the cured product (Comparative example 2) prepared by the photosensitive resin composition which does not include the thermal acid generator (D), the cured products (Examples 1 to 5) prepared by the photosensitive resin composition which includes the thermal acid generator (D) have better high-temperature resistance and low-temperature resistance. Therefore, when the photosensitive resin composition includes the thermal acid generator (D), the cured product formed by the photosensitive resin composition may have better high-temperature resistance and low-temperature resistance.

In addition, compared to the cured product (Comparative example 3) prepared by the photosensitive resin composition which does not include the epoxy monomer (B1) having a specific structure and the thermal acid generator (D), the cured products (Examples 1 to 5) prepared by the photosensitive resin composition which includes the epoxy monomer (B1) having a specific structure and the thermal acid generator (D) have better low-temperature resistance. Therefore, when the photosensitive resin composition includes the epoxy monomer (B1) having a specific structure and the thermal acid generator (D), the cured product formed by the photosensitive resin composition may have better low-temperature resistance.

Based on the above, when the photosensitive resin composition of the invention includes the epoxy monomer (B1) having a specific structure and the thermal acid generator (D) including a hexafluoroonium salt, the cured products formed by the photosensitive resin composition have good light transmittance, curvature change rate of developed residual film corresponding to exposure amount, developability, high-temperature resistance and low-temperature resistance, and may be applied to an optical element, thus improving the performance of a device using the optical element.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A photosensitive resin composition, comprising:
an alkali-soluble resin (A), having a weight average molecular weight of 5,000 to 40,000;
a polymerizable monomer (B), comprising an epoxy monomer (B1), an ethylenically unsaturated monomer (B2) or the combination thereof;
a thermal acid generator (D), comprising a hexafluoroonium salt;
a photoinitiator (E); and
a solvent (F),
wherein the epoxy monomer (B1) comprises a compound represented by the following Formula (B-1): 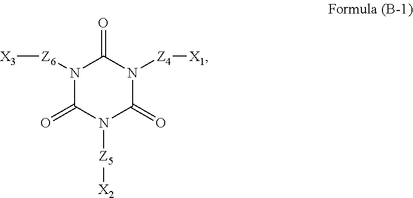
in Formula (B-1), X₁, X₂ and X₃ each comprise at least one epoxy group, Z₄, Z₅ and Z₆ each comprise an alkylene group having 1 to 6 carbon atoms, 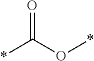 [SMILES: *OC(*)=O]
or a combination thereof, X₁, X₂ and X₃ are the same or different, Z₄, Z₅ and Z₆ are the same or different, * indicates a bonding position.

2. The photosensitive resin composition according to claim 1, wherein in Formula (B-1), X₁, X₂ and X₃ each indicate 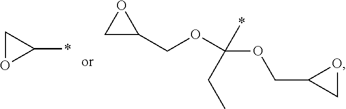
Z₄, Z₅ and Z₆ each indicate an alkylene group having 1 to 6 carbon atoms or 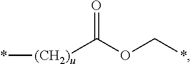
v indicates an integer of 1 to 4, * indicates a bonding position.

3. The photosensitive resin composition according to claim 1, wherein the epoxy monomer (B1) comprises at least one of compounds represented by the following Formula (B-2) to Formula (B-3): 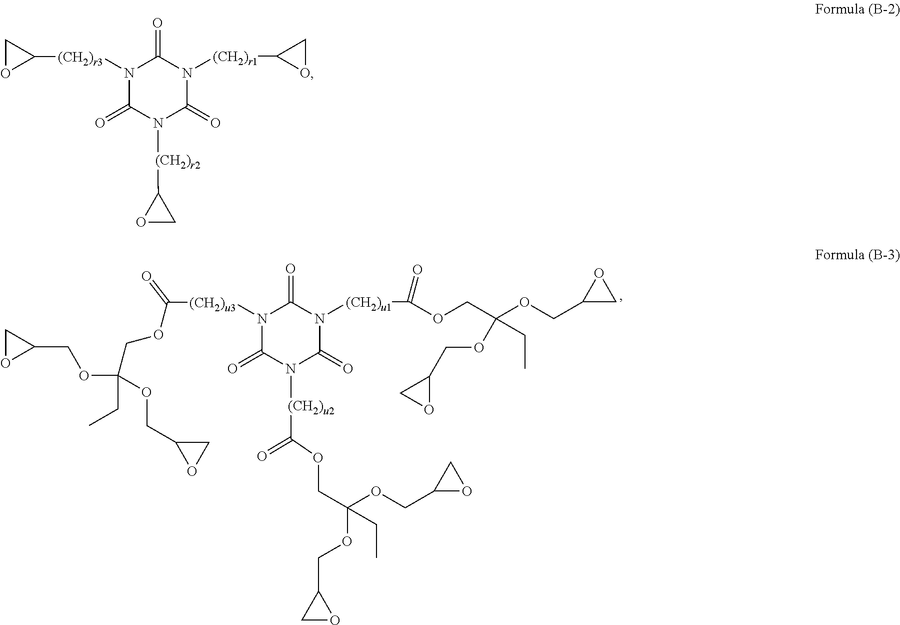
in Formula (B-2) and Formula (B-3), r1 to r3 each indicate an integer of 1 to 6, u1 to u3 each indicate an integer of 1 to 6.

4. The photosensitive resin composition according to claim 1, wherein the alkali-soluble resin (A) comprises at least one of structural units represented by the following Formula (A-1) to Formula (A-4): 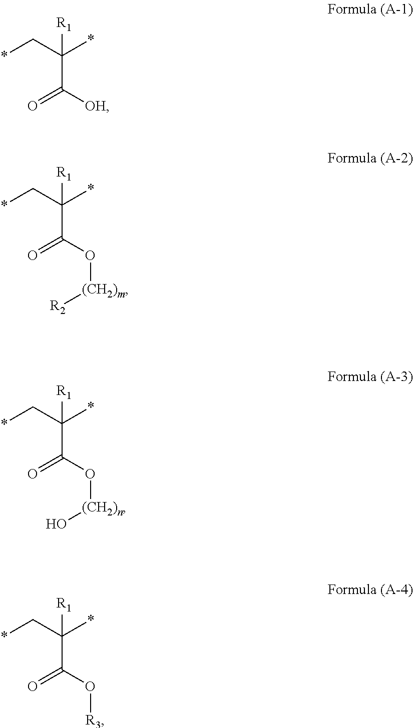
in Formula (A-1) to Formula (A-4), R₁ indicates a hydrogen atom or a methyl group, R₂ indicates a cycloalkyl group having 3 to 6 carbon atoms, R₃ indicates an alkyl group having 1 to 12 carbon atoms, m indicates an integer of 0 to 6, n indicates an integer of 1 to 4, * indicates a bonding position.

5. The photosensitive resin composition according to claim 4, based on a total usage amount of 100 parts by weight of the photosensitive resin composition, a usage amount of a monomer forming the structural unit represented by Formula (A-1) is 2.7 parts by weight to 16.5 parts by weight, a usage amount of a monomer forming the structural unit represented by Formula (A-2) is 4.1 parts by weight to 12.9 parts by weight, a usage amount of a monomer forming the structural unit represented by Formula (A-3) is 3.3 parts by weight to 16.9 parts by weight, or a usage amount of a monomer forming the structural unit represented by Formula (A-4) is 8.0 parts by weight to 20.0 parts by weight.

6. The photosensitive resin composition according to claim 1, a number of functional groups of the ethylenically unsaturated monomer (B2) is greater than or equal to 3.

7. The photosensitive resin composition according to claim 1, wherein the ethylenically unsaturated monomer (B2) includes a compound represented by the following Formula (B-4): 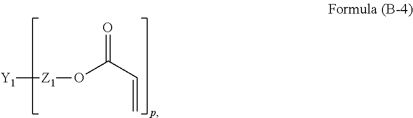
in Formula (B-4), Y₁ indicates an oxygen atom or CR₄, R₄ indicates a hydrogen atom or an alkyl group having 1 to 4 carbon atoms, Z₁ indicates an alkylene group having 1 to 11 carbon atoms, *—OZ₂—* or a combination thereof, Z₂ indicates an alkylene group having 2 to 3 carbon atoms, p indicates 2 or 3, * indicates a bonding position,
structures in parentheses are the same or different from each other.

8. The photosensitive resin composition according to claim 1, wherein the ethylenically unsaturated monomer (B2) comprises at least one of compounds represented by the following Formula (B-5) to Formula (B-7): 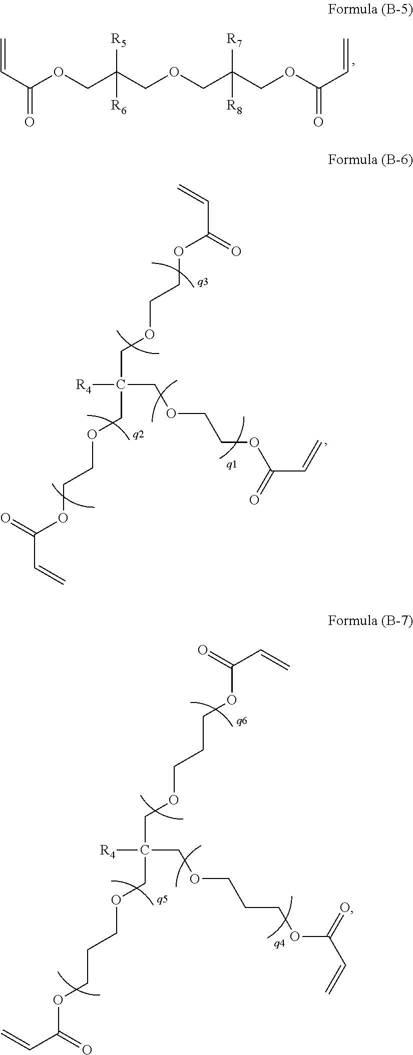
in Formula (B-5) to Formula (B-7), R₄ indicates a hydrogen atom or an alkyl group having 1 to 4 carbon atoms, R₅ to R₈ each indicates a hydrogen atom, an alkyl group having 1 to 4 carbon atoms, 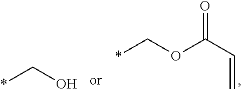
q₁ to q₆ each indicate an integer of 0 to 6, a sum of q₁, q₂ and q₃ is an integer of 0 to 6, a sum of q₄, q₅ and q₆ is an integer of 0 to 6, * indicates a bonding position.

9. The photosensitive resin composition according to claim 1, further comprising an antioxidant (C), wherein the antioxidant (C) comprises a compound represented by the following Formula (C-1): 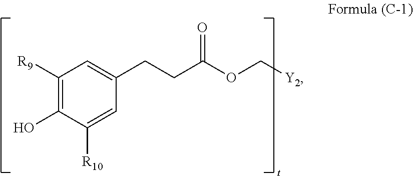
in Formula (C-1), R₉ and R₁₀ each indicate an alkyl group having 1 to 4 carbon atoms,
when t is 2, Y₂ indicates a single bond, a sulfur atom, a methylene group or a combination thereof,
when t is 3, Y₂ indicates a trivalent methyl group,
when t is 4, Y₂ indicates a carbon atom.

10. The photosensitive resin composition according to claim 1, wherein the thermal acid generator (D) comprises a hexafluorophosphate salt.

11. The photosensitive resin composition according to claim 1, wherein based on a total usage amount of 100 parts by weight of the photosensitive resin composition, a usage amount of the thermal acid generator (D) is 0.1 part by weight to 5.0 parts by weight.

12. The photosensitive resin composition according to claim 1, wherein the photoinitiator (E) includes a phenylphosphine oxide compound.

13. The photosensitive resin composition according to claim 1, wherein the solvent (F) comprises propylene glycol methyl ether acetate, tetrahydrofuran, chloroform or a combination thereof.

14. The photosensitive resin composition according to claim 1, further comprising a surfactant (G), wherein the surfactant (G) comprises a fluorine-based surfactant.

15. The photosensitive resin composition according to claim 1, wherein based on a total usage amount of 100 parts by weight of the photosensitive resin composition, a usage amount of the alkali-soluble resin (A) is 13 parts by weight to 50 parts by weight, a usage amount of the polymerizable monomer (B) is 6 parts by weight to 30 parts by weight, a usage amount of the photoinitiator (E) is 0.3 part by weight to 3.3 parts by weight, and a usage amount of the solvent (F) is 18 parts by weight to 65 parts by weight.

16. A cured product formed by curing the photosensitive resin composition according to claim 1.

17. The cured product according to claim 16, having a thickness of 5 μm to 67 μm.

18. The cured product composition according to claim 17, having a transmittance at a wavelength of 400 nm to 1100 nm being greater than or equal to 95%.

19. The cured product composition according to claim 17, having photosensitive properties as follows: x (J/m²) indicating exposure amount, y indicating a ratio (y=Δh/h) of developed residual film thickness Δh (μm) to a coating film thickness h (μm) before development, a relationship between a developed residual film (y) and a exposure amount (x) being y=α·log₁₀(x)±β, and α being 0.4≤α≤0.6.
